(19) United States
(12) Patent Application Publication
(10) Pub. No.: US 2026/0282558 A1
(43) Pub. Date: Sep. 17, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Teruyuki OHASHI, Kawasaki Kanagawa (JP); Shun TAKEDA, Saitama Saitama (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/529,340

(22) Filed: Feb. 4, 2026

(30) Foreign Application Priority Data
Feb. 6, 2025 (JP) 2025-018507

(51) Int. Cl. H10D 89/10; H10D 62/832; H10D 80/30; H10W 40/20; H10W 90/00

(52) U.S. Cl. CPC H10D 89/105; H10D 62/8325; H10D 80/30; H10W 40/233; H10W 90/753

(57) ABSTRACT

A semiconductor device of embodiments includes: an insulating substrate having a first side, a second side, a third side, and a fourth side; a first terminal; a second terminal; an output terminal; a first semiconductor chip group and a second semiconductor chip group both having semiconductor chips arranged in a matrix. The first semiconductor chip group includes a first semiconductor chip closest to the first side and the third side. The second semiconductor chip group includes a second semiconductor chip closest to the second side and the third side and a third semiconductor chip adjacent to the second semiconductor chip in the second direction. A first distance between the first semiconductor chip and the third side is larger than a second distance between the second semiconductor chip and the third side and smaller than a third distance between the third semiconductor chip and the third side.

### CROSS-REFERENCE TO RELATED APPLICATION

This application is based upon and claims the benefit of priority from Japanese Patent Application No. 2025-018507, filed on Feb. 6, 2025, the entire contents of which are incorporated herein by reference.

### FIELD

Embodiments described herein relate generally to a semiconductor device.

### BACKGROUND

In a power semiconductor module, for example, a semiconductor chip is mounted on a metal base with an insulating substrate interposed therebetween. The semiconductor chip is, for example, a metal oxide field effect transistor (MOSFET). It is desired to reduce the size of a cooling system for cooling the power semiconductor module.

### BRIEF DESCRIPTION OF THE DRAWINGS

FIG. 1 is a schematic top view of a semiconductor device according to a first embodiment;

FIG. 2 is a schematic cross-sectional view of the semiconductor device according to the first embodiment;

FIG. 3 is an equivalent circuit diagram of the semiconductor device according to the first embodiment;

FIG. 4 is a schematic top view of a part of the semiconductor device according to the first embodiment;

FIG. 5 is a schematic top view of a semiconductor device according to a comparative example;

FIG. 6 is a schematic top view of a part of the semiconductor device according to the comparative example;

FIG. 7 is a schematic top view of a part of a semiconductor device according to a second embodiment;

FIG. 8 is a schematic top view of a part of a semiconductor device according to a third embodiment; and

FIG. 9 is a schematic top view of a part of a semiconductor device according to a fourth embodiment.

### DETAILED DESCRIPTION

A semiconductor device of embodiments includes: an insulating substrate having a first side, a second side opposite to the first side in a first direction, a third side, and a fourth side opposite to the third side in a second direction perpendicular to the first direction; a first terminal provided on a side of the first side; a second terminal provided on a side of the first side; an output terminal provided on a side of the second side; a first metal layer provided on the insulating substrate, including a first region and a second region, and electrically connected to the first terminal in the first region; a second metal layer provided on the insulating substrate, including a third region, and electrically connected to the second terminal in the third region; a third metal layer provided on the insulating substrate, including a fourth region, a fifth region, and a sixth region, and electrically connected to the output terminal in the fourth region, the sixth region being provided between the second region and the first side and the fifth region being provided between the second region and the third side; a first semiconductor chip group provided on the second region and including a plurality of semiconductor chips arranged in a matrix in the first and second directions, each semiconductor chip having a first upper electrode and a first lower electrode, the first upper electrode being electrically connected to the third metal layer, and the first lower electrode being electrically connected to the first metal layer; and a second semiconductor chip group provided on the sixth region and including a plurality of semiconductor chips arranged in a matrix in the first and second directions, each semiconductor chip having a second upper electrode and a second lower electrode, the second upper electrode being electrically connected to the second metal layer, and the second lower electrode being electrically connected to the third metal layer, wherein the first semiconductor chip group includes a first semiconductor chip closest to the first side and the third side in the first semiconductor chip group, the second semiconductor chip group includes a second semiconductor chip closest to the second side and the third side in the second semiconductor chip group and a third semiconductor chip adjacent to the second semiconductor chip in the second direction, a first distance between the first semiconductor chip and the third side in the second direction is larger than a second distance between the second semiconductor chip and the third side in the second direction, and the first distance is smaller than a third distance between the third semiconductor chip and the third side in the second direction.

In this specification, the same or similar members are denoted by the same reference numerals, and the repeated descriptions thereof may be omitted.

In this specification, in order to show the positional relationship of components and the like, the upper direction of the diagram may be described as “upper” and the lower direction of the diagram may be described as “lower”. In this specification, the concepts of “upper” and “lower” do not necessarily indicate the relationship with the direction of gravity.

### First Embodiment

A semiconductor device according to a first embodiment includes: an insulating substrate having a first side, a second side opposite to the first side in a first direction, a third side, and a fourth side opposite to the third side in a second direction perpendicular to the first direction; a first terminal provided on a side of the first side; a second terminal provided on a side of the first side; an output terminal provided on a side of the second side; a first metal layer provided on the insulating substrate, including a first region and a second region, and electrically connected to the first terminal in the first region; a second metal layer provided on the insulating substrate, including a third region, and electrically connected to the second terminal in the third region; a third metal layer provided on the insulating substrate, including a fourth region, a fifth region, and a sixth region, and electrically connected to the output terminal in the fourth region, the sixth region being provided between the second region and the first side and the fifth region being provided between the second region and the third side; a first semiconductor chip group provided on the second region and including a plurality of semiconductor chips arranged in a matrix in the first and second directions, each semiconductor chip having a first upper electrode and a first lower electrode, the first upper electrode being electrically connected to the third metal layer, and the first lower electrode being electrically connected to the first metal layer; and a second semiconductor chip group provided on the sixth region and including a plurality of semiconductor chips arranged in a matrix in the first and second directions, each semiconductor chip having a second upper electrode and a second lower electrode, the second upper electrode being electrically connected to the second metal layer, and the second lower electrode being electrically connected to the third metal layer. The first semiconductor chip group includes a first semiconductor chip closest to the first side and the third side in the first semiconductor chip group. The second semiconductor chip group includes a second semiconductor chip closest to the second side and the third side in the second semiconductor chip group and a third semiconductor chip adjacent to the second semiconductor chip in the second direction. A first distance between the first semiconductor chip and the third side in the second direction is larger than a second distance between the second semiconductor chip and the third side in the second direction. The first distance is smaller than a third distance between the third semiconductor chip and the third side in the second direction.

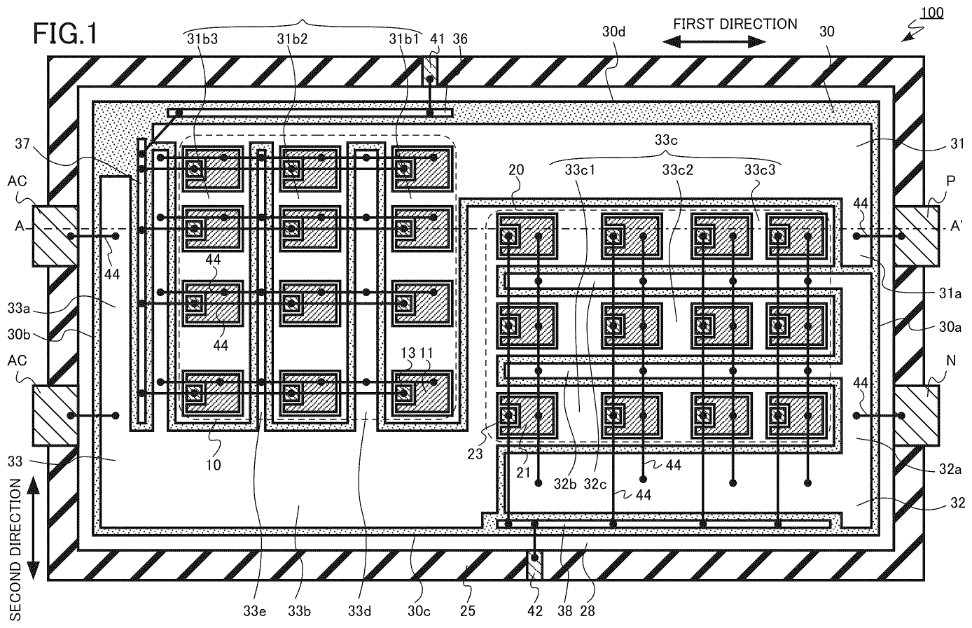

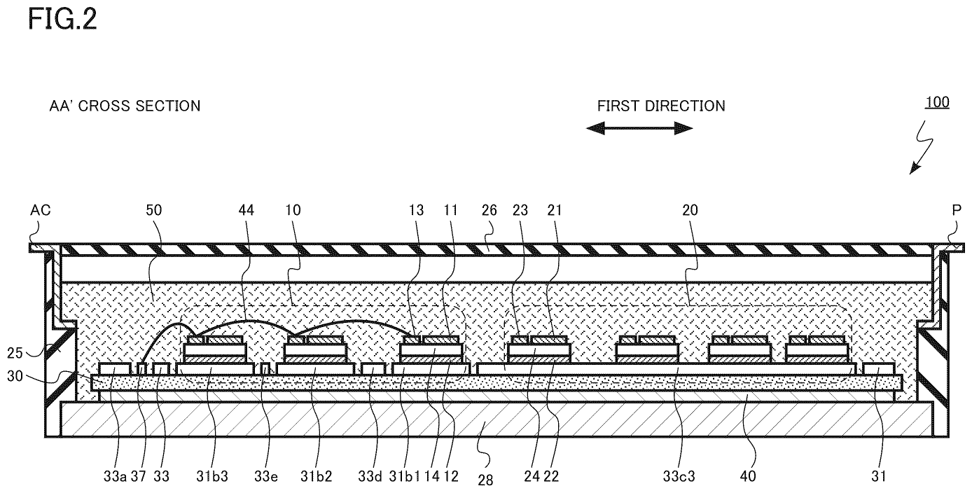

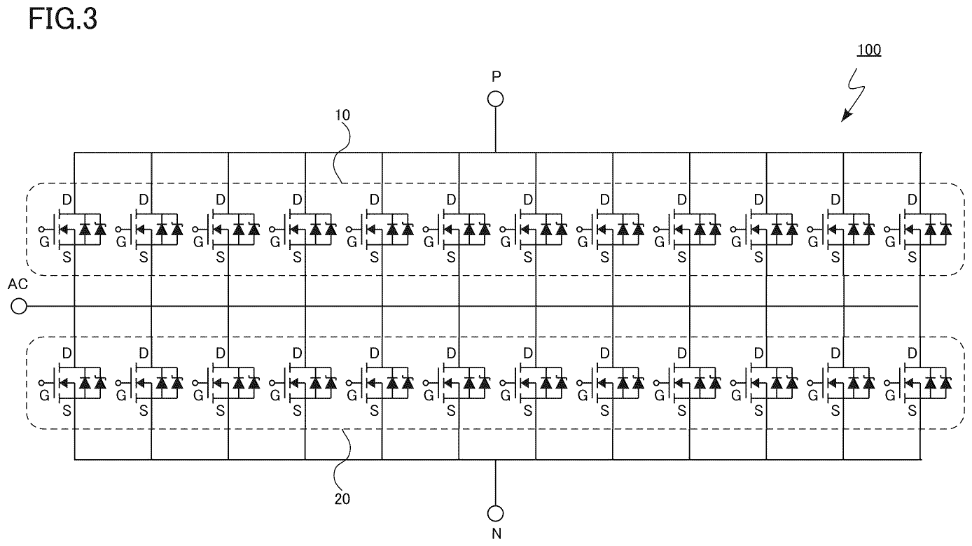

FIG. 1 is a schematic top view of the semiconductor device according to the first embodiment. FIG. 2 is a schematic cross-sectional view of the semiconductor device according to the first embodiment. FIG. 2 is a cross-sectional view taken along the line AA′ of FIG. 1. FIG. 3 is an equivalent circuit diagram of the semiconductor device according to the first embodiment.

The semiconductor device according to the first embodiment is a power semiconductor module 100. As shown in FIG. 3, the power semiconductor module 100 according to the first embodiment is a so-called “2in1” type module in which a half-bridge circuit can be configured by one module. For example, a three-phase inverter circuit can be configured by using three power semiconductor modules 100 according to the first embodiment.

As shown in FIG. 3, the power semiconductor module 100 includes a positive terminal P (first terminal), a negative terminal N (second terminal), an AC output terminal AC (output terminal), a high-side MOSFET, and a low-side MOSFET.

As shown in FIG. 3, each of the high-side MOSFET and the low-side MOSFET is formed by a plurality of MOSFETs connected in parallel. The plurality of MOSFETs that form the high-side MOSFET will be referred to as a high-side MOSFET group 10 (first semiconductor chip group). The plurality of MOSFETs that form the low-side MOSFET will be referred to as a low-side MOSFET group 20 (second semiconductor chip group).

Each MOSFET (semiconductor chip) includes a built-in Schottky barrier diode (SBD) in addition to a pn junction diode. The SBD has a function of allowing a freewheeling current to flow therethrough. The SBD functions as a freewheeling diode. Each MOSFET is formed using silicon carbide (SiC).

The high-side MOSFET group 10 of the power semiconductor module 100 includes 12 MOSFETs. In addition, the low-side MOSFET group 20 of the power semiconductor module 100 includes 12 MOSFETs. The number of MOSFETs forming the high-side MOSFET group 10 and the number of MOSFETs forming the low-side MOSFET group 20 are not limited to twelve. The number of MOSFETs forming the high-side MOSFET group 10 and the number of MOSFETs forming the low-side MOSFET group 20 may be four or more.

As shown in FIGS. 1 to 3, the power semiconductor module 100 according to the first embodiment includes the positive terminal P (first terminal), the negative terminal N (second terminal), the AC output terminal AC (output terminal), the high-side MOSFET group 10 (first semiconductor chip group), the low-side MOSFET group 20 (second semiconductor chip group), a resin case 25, a lid 26, a metal base 28, an insulating substrate 30, a first metal layer 31, a second metal layer 32, a third metal layer 33, a first gate metal layer 36, a second gate metal layer 37, a third gate metal layer 38, a back surface metal layer 40, a first gate terminal 41, a second gate terminal 42, a bonding wire 44, and a sealing resin 50.

Each MOSFET (semiconductor chip) forming the high-side MOSFET group 10 includes a first source electrode 11 (first upper electrode), a first drain electrode 12 (first lower electrode), a first gate electrode 13, and a first silicon carbide layer 14 (silicon carbide layer).

Each MOSFET (semiconductor chip) forming the low-side MOSFET group 20 includes a second source electrode 21 (second upper electrode), a second drain electrode 22 (second lower electrode), a second gate electrode 23, and a second silicon carbide layer 24 (silicon carbide layer).

The insulating substrate 30 includes a first side 30a, a second side 30b, a third side 30c, and a fourth side 30d.

The first metal layer 31 includes a first region 31a and a second region 31b. The second region 31b has a first portion 31b1, a second portion 31b2, and a third portion 31b3.

The second metal layer 32 includes a third region 32a, a ninth region 32b, and a tenth region 32c.

The third metal layer 33 includes a fourth region 33a, a fifth region 33b, a sixth region 33c, a seventh region 33d, and an eighth region 33e. The sixth region 33c has a fourth portion 33c1, a fifth portion 33c2, and a sixth portion 33c3.

FIG. 1 is a top view of the power semiconductor module 100 with the lid 26 and the sealing resin 50 removed.

The metal base 28 is, for example, copper. For example, when the power semiconductor module 100 is mounted on a product, a cooling system (not shown) is connected to the back surface of the metal base 28. The cooling system is, for example, a liquid cooling system or an air cooling system.

The insulating substrate 30 is provided on the metal base 28. The insulating substrate 30 is provided between the metal base 28 and the high-side MOSFET group 10. The insulating substrate 30 is provided between the metal base 28 and the low-side MOSFET group 20.

The insulating substrate 30 has a function of electrically separating the metal base 28 and the high-side MOSFET group 10 from each other. The insulating substrate 30 has a function of electrically separating the metal base 28 from the low-side MOSFET group 20 from each other.

The insulating substrate 30 has, for example, a quadrangular shape. The insulating substrate 30 has, for example, a rectangular shape.

The insulating substrate 30 has the first side 30a and the second side 30b opposite to the first side 30a in a first direction. In addition, the insulating substrate 30 has the third side 30c and the fourth side 30d opposite to the third side 30c in a second direction perpendicular to the first direction. The first side 30a and the second side 30b are parallel to each other. The third side 30c and the fourth side 30d are parallel to each other.

In FIG. 1, the left-right direction is the first direction. In addition, in FIG. 1, the up-down direction is the second direction. In FIG. 1, the right side of the insulating substrate 30 is the first side 30a, the left side of the insulating substrate 30 is the second side 30b, the bottom side of the insulating substrate 30 is the third side 30c, and the top side of the insulating substrate 30 is the fourth side 30d.

The insulating substrate 30 is, for example, a ceramic substrate or a resin substrate. The insulating substrate 30 is, for example, an aluminum oxide, an aluminum nitride, or a silicon nitride.

The first metal layer 31, the second metal layer 32, the third metal layer 33, the first gate metal layer 36, the second gate metal layer 37, and the third gate metal layer 38 are provided on the surface of the insulating substrate 30. The first metal layer 31, the second metal layer 32, the third metal layer 33, the first gate metal layer 36, the second gate metal layer 37, and the third gate metal layer 38 are metals. The first metal layer 31, the second metal layer 32, the third metal layer 33, the first gate metal layer 36, the second gate metal layer 37, and the third gate metal layer 38 are, for example, copper.

The first metal layer 31 includes the first region 31a and the second region 31b. The first metal layer 31 is electrically connected to the positive terminal P in the first region 31a. The first region 31a and the positive terminal P are electrically connected to each other by using, for example, the bonding wire 44.

The second metal layer 32 includes the third region 32a. The second metal layer 32 is electrically connected to the negative terminal N in the third region 32a. The third region 32a and the negative terminal N are electrically connected to each other by using, for example, the bonding wire 44.

The third metal layer 33 includes the fourth region 33a, the fifth region 33b, and the sixth region 33c. The third metal layer 33 is electrically connected to the AC output terminal AC in the fourth region 33a. The fourth region 33a and the AC output terminal AC are electrically connected to each other by using, for example, the bonding wire 44.

The fifth region 33b of the third metal layer 33 is provided between the second region 31b of the first metal layer 31 and the third side 30c. The sixth region 33c of the third metal layer 33 is provided between the second region 31b of the first metal layer 31 and the first side 30a.

The back surface metal layer 40 is provided on the back surface of the insulating substrate 30. The back surface metal layer 40 is, for example, copper. The back surface metal layer 40 is bonded to the metal base 28 using, for example, a solder layer or a silver nanoparticle layer (not shown).

The resin case 25 is provided around the metal base 28 and the insulating substrate 30. A part of the resin case 25 is provided on the metal base 28. The resin case 25 has a function of protecting the high-side MOSFET group 10, the low-side MOSFET group 20, and the insulating substrate 30.

The lid 26 is provided on the resin case 25. The lid 26 has a function of protecting the high-side MOSFET group 10, the low-side MOSFET group 20, and the insulating substrate 30.

The high-side MOSFET group 10 is provided on the first metal layer 31. The high-side MOSFET group 10 is provided on the second region 31b of the first metal layer 31.

Each of the MOSFETs forming the high-side MOSFET group 10 includes the first source electrode 11, the first drain electrode 12, the first gate electrode 13, and the first silicon carbide layer 14. The first silicon carbide layer 14 is provided between the first source electrode 11 and the first drain electrode 12. The first silicon carbide layer 14 is provided between the first gate electrode 13 and the first drain electrode 12.

The first source electrode 11 is electrically connected to the third metal layer 33. The first source electrode 11 and the third metal layer 33 are electrically connected to each other by using, for example, the bonding wire 44. The bonding wire 44 that electrically connects the first source electrode 11 and the third metal layer 33 to each other extends, for example, in the first direction.

The first drain electrode 12 is electrically connected to the first metal layer 31. The first drain electrode 12 is electrically connected to the second region 31b of the first metal layer 31. The first drain electrode 12 is electrically connected to the first metal layer 31 using, for example, a solder layer or a silver nanoparticle layer (not shown).

The first gate electrode 13 is electrically connected to the first gate terminal 41. The first gate electrode 13 is electrically connected to the first gate terminal 41 through the first gate metal layer 36 and the second gate metal layer 37. The first gate electrode 13 and the first gate terminal 41 are electrically connected to each other by using, for example, the bonding wire 44.

The low-side MOSFET group 20 is provided on the third metal layer 33. The low-side MOSFET group 20 is provided on the sixth region 33c of the third metal layer 33.

The low-side MOSFET group 20 is provided between the high-side MOSFET group 10 and the first side 30a. The low-side MOSFET group 20 is provided on a side of the first side 30a of the insulating substrate 30. The high-side MOSFET group 10 is provided on a side of the second side 30b of the insulating substrate 30.

Each of the MOSFETs forming the low-side MOSFET group 20 includes the second source electrode 21, the second drain electrode 22, the second gate electrode 23, and the second silicon carbide layer 24. The second silicon carbide layer 24 is provided between the second source electrode 21 and the second drain electrode 22. The second silicon carbide layer 24 is provided between the second gate electrode 23 and the second drain electrode 22.

The second source electrode 21 is electrically connected to the second metal layer 32. The second source electrode 21 and the second metal layer 32 are electrically connected to each other by using, for example, the bonding wire 44. The bonding wire 44 that electrically connects the second source electrode 21 and the second metal layer 32 to each other extends, for example, in the second direction.

The second drain electrode 22 is electrically connected to the third metal layer 33. The second drain electrode 22 is electrically connected to the sixth region 33c of the third metal layer 33. The second drain electrode 22 is electrically connected to the third metal layer 33 using, for example, a solder layer or a silver nanoparticle layer (not shown).

The second gate electrode 23 is electrically connected to the second gate terminal 42. The second gate electrode 23 is electrically connected to the second gate terminal 42 through the third gate metal layer 38. The second gate electrode 23 and the second gate terminal 42 are electrically connected to each other by using, for example, the bonding wire 44.

The sealing resin 50 is filled into the resin case 25. The sealing resin 50 is surrounded by the resin case 25. The sealing resin 50 covers the high-side MOSFET group 10, the low-side MOSFET group 20, and the insulating substrate 30.

The sealing resin 50 has a function of protecting the high-side MOSFET group 10, the low-side MOSFET group 20, and the insulating substrate 30. In addition, the sealing resin 50 has a function of insulating the high-side MOSFET group 10, the low-side MOSFET group 20, and the insulating substrate 30.

The sealing resin 50 contains a resin. The sealing resin 50 is, for example, a silicone gel. As the sealing resin 50, for example, an epoxy resin, a polyimide resin, or other resins can be applied.

The positive terminal P is provided on a side of the first side 30a of the insulating substrate 30. For example, in FIG. 1, the positive terminal P is provided on the right side of the insulating substrate 30.

The positive terminal P is electrically connected to the first metal layer 31. The positive terminal P is electrically connected to the first region 31a of the first metal layer 31. The positive terminal P is electrically connected to the first region 31a by using, for example, the bonding wire 44.

For example, a positive voltage is applied to the positive terminal P from the outside.

The positive terminal P is formed of metal. The positive terminal P is, for example, copper.

The negative terminal N is provided on a side of the first side 30a of the insulating substrate 30. The negative terminal N and the positive terminal P are provided on the same side of the insulating substrate 30. For example, in FIG. 1, the negative terminal N is provided on the right side of the insulating substrate 30.

The negative terminal N is electrically connected to the second metal layer 32. The negative terminal N is electrically connected to the third region 32a of the second metal layer 32. The negative terminal N is electrically connected to the third region 32a by using, for example, the bonding wire 44.

For example, a negative voltage is applied to the negative terminal N from the outside.

The negative terminal N is formed of metal. The negative terminal N is, for example, copper.

The AC output terminal AC is provided on the second side 30b of the insulating substrate 30. The AC output terminal AC is provided on a side opposite to the positive terminal P and the negative terminal N with the insulating substrate 30 interposed therebetween. In FIG. 1, the AC output terminal AC is provided on the left side of the insulating substrate 30. FIG. 1 illustrates a case where there are two AC output terminals AC.

The AC output terminal AC is electrically connected to the third metal layer 33. The AC output terminal AC is electrically connected to the fourth region 33a of the third metal layer 33. The AC output terminal AC is electrically connected to the fourth region 33a by using, for example, the bonding wire 44.

The AC output terminal AC outputs the output current of the half-bridge circuit.

The first gate terminal 41 is electrically connected to the first gate electrode 13 of the MOSFET in the high-side MOSFET group 10. The second gate terminal 42 is electrically connected to the second gate electrode 23 of the MOSFET in the low-side MOSFET group 20.

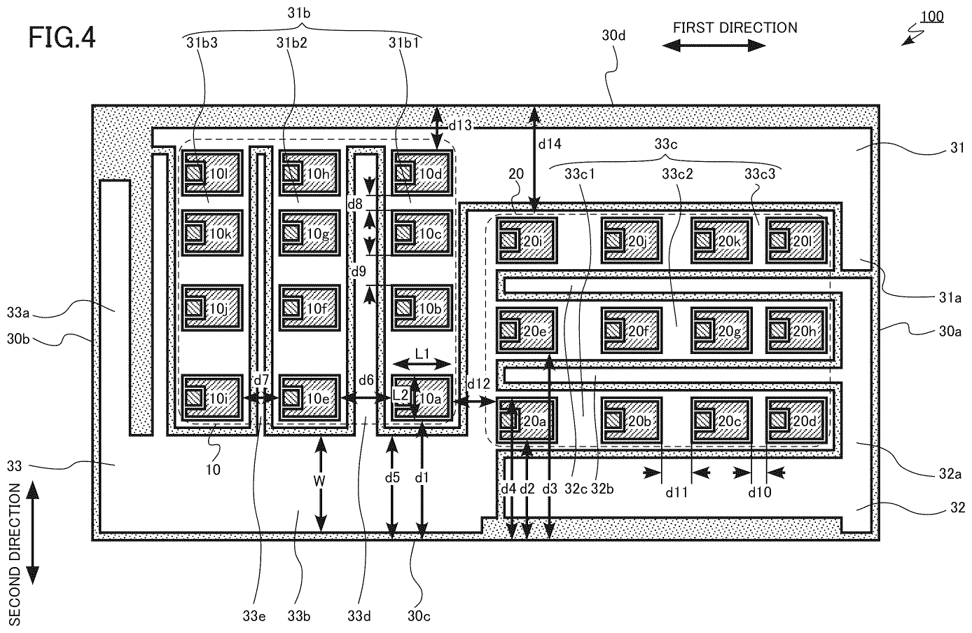

FIG. 4 is a schematic top view of a part of the semiconductor device according to the first embodiment. FIG. 4 shows only the high-side MOSFET group 10, the low-side MOSFET group 20, the insulating substrate 30, the first metal layer 31, the second metal layer 32, and the third metal layer 33 in FIG. 1. FIG. 4 is a diagram showing the arrangement of the MOSFETs forming the high-side MOSFET group 10 and the low-side MOSFET group 20 and the patterns of the first metal layer 31, the second metal layer 32, and the third metal layer 33.

In the high-side MOSFET group 10, a plurality of semiconductor chips are arranged in a matrix in the first and second directions. In the high-side MOSFET group 10, 12 MOSFETs (semiconductor chips) are arranged in a matrix in the first and second directions.

In the high-side MOSFET group 10, a first high-side MOSFET 10a (first semiconductor chip), a second high-side MOSFET 10b (ninth semiconductor chip), a third high-side MOSFET 10c (eighth semiconductor chip), a fourth high-side MOSFET 10d (seventh semiconductor chip, thirteenth semiconductor chip), a fifth high-side MOSFET 10e (fourth semiconductor chip), a sixth high-side MOSFET 10f, a seventh high-side MOSFET 10g, an eighth high-side MOSFET 10h, a ninth high-side MOSFET 10i (fifth semiconductor chip), a tenth high-side MOSFET 10j, an eleventh high-side MOSFET 10k, and a twelfth high-side MOSFET 10l are arranged in a matrix.

The second region 31b of the first metal layer 31 includes the first portion 31b1 extending in the second direction, the second portion 31b2 extending in the second direction, and the third portion 31b3 extending in the second direction. The first portion 31b1, the second portion 31b2, and the third portion 31b3 are spaced from each other in the first direction. The second portion 31b2 is provided between the first portion 31b1 and the second side 30b. The third portion 31b3 is provided between the first portion 31b1 and the second side 30b.

The first high-side MOSFET 10a (first semiconductor chip), the second high-side MOSFET 10b (ninth semiconductor chip), the third high-side MOSFET 10c (eighth semiconductor chip), and the fourth high-side MOSFET 10d (seventh semiconductor chip, thirteenth semiconductor chip) are provided on the first portion 31b1. The fifth high-side MOSFET 10e (fourth semiconductor chip), the sixth high-side MOSFET 10f, the seventh high-side MOSFET 10g, and the eighth high-side MOSFET 10h are provided on the second portion 31b2. The ninth high-side MOSFET 10i (fifth semiconductor chip), the tenth high-side MOSFET 10j, the eleventh high-side MOSFET 10k, and the twelfth high-side MOSFET 10l are provided on the third portion 31b3.

The third metal layer 33 includes the seventh region 33d connected to the fifth region 33b and extending in the second direction and the eighth region 33e connected to the fifth region 33b and extending in the second direction. The seventh region 33d is provided between the first portion 31b1 and the second portion 31b2. The eighth region 33e is provided between the second portion 31b2 and the third portion 31b3.

In the low-side MOSFET group 20, a plurality of semiconductor chips are arranged in a matrix in the first and second directions. In the low-side MOSFET group 20, twelve MOSFETs (semiconductor chips) are arranged in a matrix in the first and second directions.

In the low-side MOSFET group 20, a first low-side

MOSFET 20a (second semiconductor chip), a second low-side MOSFET 20b (twelfth semiconductor chip), a third low-side MOSFET 20c (eleventh semiconductor chip), a fourth low-side MOSFET 20d (tenth semiconductor chip), a fifth low-side MOSFET 20e (third semiconductor chip), a sixth low-side MOSFET 20f, a seventh low-side MOSFET 20g, an eighth low-side MOSFET 20h, a ninth low-side MOSFET 20i (sixth semiconductor chip, fourteenth semiconductor chip), a tenth low-side MOSFET 20j, an eleventh low-side MOSFET 20k, and a twelfth low-side MOSFET 20l are arranged in a matrix.

The sixth region 33c of the third metal layer 33 includes the fourth portion 33c1 extending in the first direction, the fifth portion 33c2 extending in the first direction, and the sixth portion 33c3 extending in the first direction. The fourth portion 33c1, the fifth portion 33c2, and the sixth portion 33c3 are spaced from each other in the second direction. The fifth portion 33c2 is provided between the fourth portion 33c1 and the fourth side 30d. The sixth portion 33c3 is provided between the fifth portion 33c2 and the fourth side 30d.

The first low-side MOSFET 20a (second semiconductor chip), the second low-side MOSFET 20b (twelfth semiconductor chip), the third low-side MOSFET 20c (eleventh semiconductor chip), and the fourth low-side MOSFET 20d (tenth semiconductor chip) are provided on the fourth portion 33c1. The fifth low-side MOSFET 20e (third semiconductor chip), the sixth low-side MOSFET 20f, the seventh low-side MOSFET 20g, and the eighth low-side MOSFET 20h are provided on the fifth portion 33c2. The ninth low-side MOSFET 20i (sixth semiconductor chip, fourteenth semiconductor chip), the tenth low-side MOSFET 20j, the eleventh low-side MOSFET 20k, and the twelfth low-side MOSFET 20l are provided on the sixth portion 33c3.

The second metal layer 32 includes the ninth region 32b connected to the third region 32a and extending in the first direction and the tenth region 32c connected to the third region 32a and extending in the first direction. The ninth region 32b is provided between the fourth portion 33c1 and the fifth portion 33c2. The tenth region 32c is provided between the fifth portion 33c2 and the sixth portion 33c3.

Of the MOSFETs in the high-side MOSFET group 10, the first high-side MOSFET 10a is closest to the first side 30a and the third side 30c. Of the MOSFETs in the low-side MOSFET group 20, the first low-side MOSFET 20a is closest to the second side 30b and the third side 30c. The fifth low-side MOSFET 20e is adjacent to the first low-side MOSFET 20a in the second direction. The first high-side MOSFET 10a, the first low-side MOSFET 20a, and the fifth low-side MOSFET 20e are examples of a first semiconductor chip, a second semiconductor chip, and a third semiconductor chip, respectively.

A first distance (d1 in FIG. 4) between the first high-side MOSFET 10a and the third side 30c in the second direction is larger than a second distance (d2 in FIG. 4) between the first low-side MOSFET 20a and the third side 30c in the second direction. In addition, the first distance d1 is smaller than a third distance (d3 in FIG. 4) between the fifth low-side MOSFET 20e and the third side 30c in the second direction.

Of the MOSFETs in the high-side MOSFET group 10, the fourth high-side MOSFET 10d is closest to the first side 30a and the fourth side 30d. Of the MOSFETs in the low-side MOSFET group 20, the ninth low-side MOSFET 20i is closest to the second side 30b and the fourth side 30d. The fourth high-side MOSFET 10d and the ninth low-side MOSFET 20i are examples of a thirteenth semiconductor chip and a fourteenth semiconductor chip, respectively.

A thirteenth distance (d13 in FIG. 4) between the fourth high-side MOSFET 10d and the fourth side 30d in the second direction is smaller than a fourteenth distance (d14 in FIG. 4) between the ninth low-side MOSFET 20i and the fourth side 30d in the second direction.

The distance between the high-side MOSFET group 10 and the third side 30c in the second direction is larger than the distance between the low-side MOSFET group 20 and the third side 30c in the second direction. In addition, the distance between the high-side MOSFET group 10 and the fourth side 30d in the second direction is smaller than the distance between the low-side MOSFET group 20 and the fourth side 30d in the second direction.

The first distance (d1 in FIG. 4) between the first high-side MOSFET 10a and the third side 30c in the second direction is, for example, smaller than the fourth distance (d4 in FIG. 4) between the end of the first low-side MOSFET 20a on the side of the fourth side 30d and the third side 30c in the second direction.

A twelfth distance (d12 in FIG. 4) between the first high-side MOSFET 10a and the first low-side MOSFET 20a in the first direction is, for example, smaller than a first length (L1 in FIG. 4) of the first high-side MOSFET 10a in the first direction.

A fifth distance (d5 in FIG. 4) between the end of the fifth region 33b of the third metal layer 33 on the side of the fourth side 30d and the third side 30c in the second direction is, for example, larger than the second distance d2.

The width (W in FIG. 4) of the fifth region 33b in the second direction is, for example, larger than a second length (L2 in FIG. 4) of the first high-side MOSFET 10a in the second direction. The width W of the fifth region 33b in the second direction is, for example, equal to or more than 5 mm and equal to or less than 10 mm.

The fifth high-side MOSFET 10e is adjacent to the first high-side MOSFET 10a in the first direction and is provided between the first high-side MOSFET 10a and the second side 30b. The ninth high-side MOSFET 10i is adjacent to the fifth high-side MOSFET 10e in the first direction and is provided between the fifth high-side MOSFET 10e and the second side 30b. The first high-side MOSFET 10a, the fifth high-side MOSFET 10e, and the ninth high-side MOSFET 10i are examples of a first semiconductor chip, a fourth semiconductor chip, and a fifth semiconductor chip, respectively.

A sixth distance (d6 in FIG. 4) between the first high-side MOSFET 10a and the fifth high-side MOSFET 10e in the first direction is, for example, larger than a seventh distance (d7 in FIG. 4) between the fifth high-side MOSFET 10e and the ninth high-side MOSFET 10i in the first direction.

Of the MOSFETs in the high-side MOSFET group 10, the fourth high-side MOSFET 10d is closest to the first side 30a and the fourth side 30d. The third high-side MOSFET 10c is adjacent to the fourth high-side MOSFET 10d in the second direction and is provided between the fourth high-side MOSFET 10d and the third side 30c. The second high-side MOSFET 10b is adjacent to the third high-side MOSFET 10c in the second direction and is provided between the third high-side MOSFET 10c and the third side 30c. The fourth high-side MOSFET 10d, the third high-side MOSFET 10c, and the second high-side MOSFET 10b are examples of a seventh semiconductor chip, an eighth semiconductor chip, and a ninth semiconductor chip, respectively.

An eighth distance (d8 in FIG. 4) between the fourth high-side MOSFET 10d and the third high-side MOSFET 10c in the second direction is, for example, smaller than a ninth distance (d9 in FIG. 4) between the third high-side MOSFET 10c and the second high-side MOSFET 10b in the second direction.

The ninth distance d9 is, for example, smaller than the distance between the second high-side MOSFET 10b and the first high-side MOSFET 10a in the second direction.

Of the MOSFETs in the low-side MOSFET group 20, the fourth low-side MOSFET 20d is closest to the first side 30a and the third side 30c. The third low-side MOSFET 20c is adjacent to the fourth low-side MOSFET 20d in the first direction and is provided between the fourth low-side MOSFET 20d and the second side 30b. The second low-side MOSFET 20b is adjacent to the third low-side MOSFET 20c in the first direction and is provided between the third low-side MOSFET 20c and the second side 30b. The fourth low-side MOSFET 20d, the third low-side MOSFET 20c, and the second low-side MOSFET 20b are examples of a tenth semiconductor chip, an eleventh semiconductor chip, and a twelfth semiconductor chip, respectively.

A tenth distance (d10 in FIG. 4) between the fourth low-side MOSFET 20d and the third low-side MOSFET 20c in the first direction is, for example, smaller than an eleventh distance (d11 in FIG. 4) between the third low-side MOSFET 20c and the second low-side MOSFET 20b in the first direction.

The eleventh distance d11 is, for example, smaller than the distance between the second low-side MOSFET 20b and the first low-side MOSFET 20a in the first direction.

Next, the function and effect of the power semiconductor module 100 according to the first embodiment will be described.

In a power semiconductor module, it is necessary to cool the power semiconductor module so that the semiconductor chips included in the power semiconductor module do not exceed the limit of their heat resistance temperature. In order to reduce the overall size of a system in which a power semiconductor module is used, it is required to reduce the size of the cooling system for cooling the power semiconductor module. In order to reduce the size of the cooling system, it is conceivable to suppress heat generation in the power semiconductor module. As a means for suppressing heat generation in the power semiconductor module, it is conceivable to reduce the thermal resistance of the power semiconductor module and the power loss of the power semiconductor module.

Thermal resistance (K/W) is a value obtained by dividing the temperature difference (K) between a heat source and a reference point by the amount of heat (W) of the heat source. Thermal resistance is an index indicating the difficulty of heat flow. In the case of a power semiconductor module, for example, thermal resistance is a value obtained by dividing the temperature difference between a semiconductor chip forming the power semiconductor module and an outer surface of a metal base of the power semiconductor module by the power applied to the semiconductor chip. By reducing the thermal resistance, for example, heat generated in the semiconductor chip can more easily flow to the metal base, thereby suppressing heat generation in the power semiconductor module.

Power loss is a loss that occurs when a current flows through an electronic circuit. When a current flows through the electronic circuit, heat is generated in proportion to the electrical resistance of the electronic circuit. The heat generated results in power loss. The power loss of a power semiconductor module includes conduction loss in an on-state in which current is flowing and switching loss that occurs when switching from the on-state to the off-state or from the off-state to the on-state. Most of these losses turn into heat, which causes heat generation in the power semiconductor module. By reducing the power loss, heat generation in the power semiconductor module can be suppressed.

A power semiconductor module using a silicon carbide semiconductor consumes more power than, for example, a power semiconductor module using a silicon semiconductor. For this reason, the heat generation density of a power semiconductor module using a silicon carbide semiconductor is higher than the heat generation density of a power semiconductor module of the same size using a silicon semiconductor. Therefore, there is a concern that the size of the cooling system will increase.

Among power semiconductor modules using silicon carbide semiconductors, particularly in the case of a power semiconductor module including a MOSFET with a built-in freewheeling diode, the heat generation density becomes even higher, and accordingly, an increase in the size of the cooling system is of greater concern. This is because both the on-current and the freewheeling current flow using the same MOSFET.

In particular, when a MOSFET with a built-in Schottky barrier diode (SBD) is included as a freewheeling diode in addition to a pn junction diode, the heat generation density becomes even higher, and accordingly, an increase in the size of the cooling system is of greater concern. This is because the conduction loss when a freewheeling current flows using an SBD is larger than the conduction loss when a freewheeling current flows using a pn junction diode.

In the power semiconductor module 100 according to the first embodiment, the high-side MOSFET group 10 and the low-side MOSFET group 20 are each formed by 12 MOSFETs. By arranging a plurality of MOSFETs on the insulating substrate 30 in a distributed manner, thermal interference between the MOSFETs can be suppressed. Therefore, the thermal resistance of the power semiconductor module 100 can be reduced.

In addition, a plurality of high-side MOSFETs in the high-side MOSFET group 10 of the power semiconductor module 100 according to the first embodiment are arranged so as to be divided into the first portion 31b1, the second portion 31b2, and the third portion 31b3 spaced from each other in the first direction. Then, the seventh region 33d of the third metal layer 33 is provided between the first portion 31b1 and the second portion 31b2, and the eighth region 33e of the third metal layer 33 is provided between the second portion 31b2 and the third portion 31b3. The first source electrode 11 of the high-side MOSFET is electrically connected to the seventh region 33d and the eighth region 33e. Through the configuration described above, variations in the length of the current path between the positive terminal P and the AC output terminal AC, which passes through each of the plurality of high-side MOSFETs, are reduced.

In addition, a plurality of low-side MOSFETs in the low-side MOSFET group 20 of the power semiconductor module 100 according to the first embodiment are arranged so as to be divided into the fourth portion 33c1, the fifth portion 33c2, and the sixth portion 33c3 spaced from each other in the second direction. Then, the ninth region 32b of the second metal layer 32 is provided between the fourth portion 33c1 and the fifth portion 33c2, and the tenth region 32c of the second metal layer 32 is provided between the fifth portion 33c2 and the sixth portion 33c3. The second source electrode 21 of the low-side MOSFET is electrically connected to the ninth region 32b and the tenth region 32c. Through the configuration described above, variations in the length of the current path between the negative terminal N and the AC output terminal AC, which passes through each of the plurality of low-side MOSFETs, are reduced.

By reducing the variation in the length of the current path between terminals passing through the respective MOSFETs, for example, current concentration is suppressed, and accordingly, an increase in thermal resistance due to localized heat generation is suppressed.

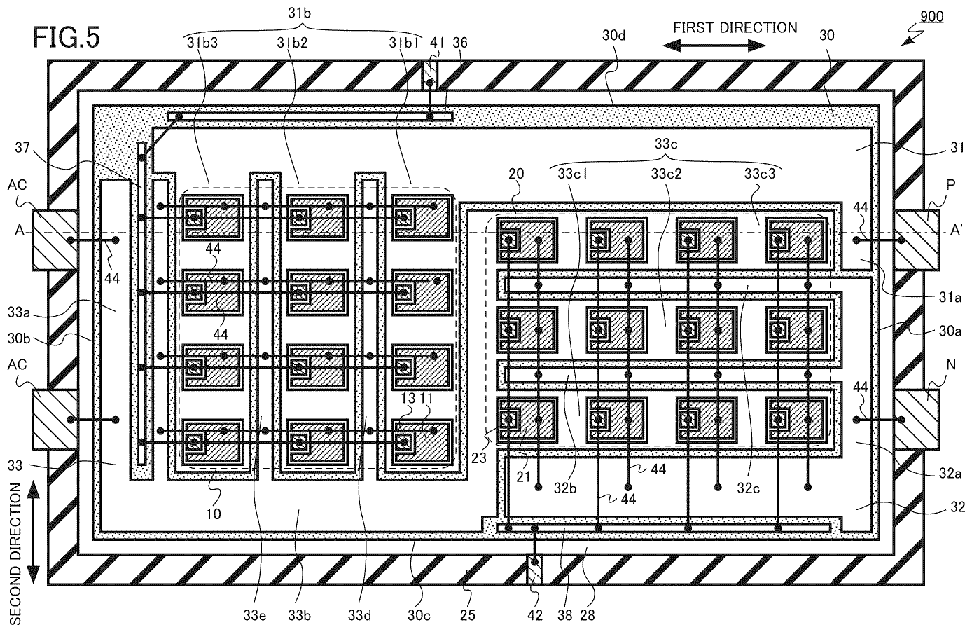

FIG. 5 is a schematic top view of a semiconductor device according to a comparative example. FIG. 5 is a diagram corresponding to FIG. 1 in the first embodiment.

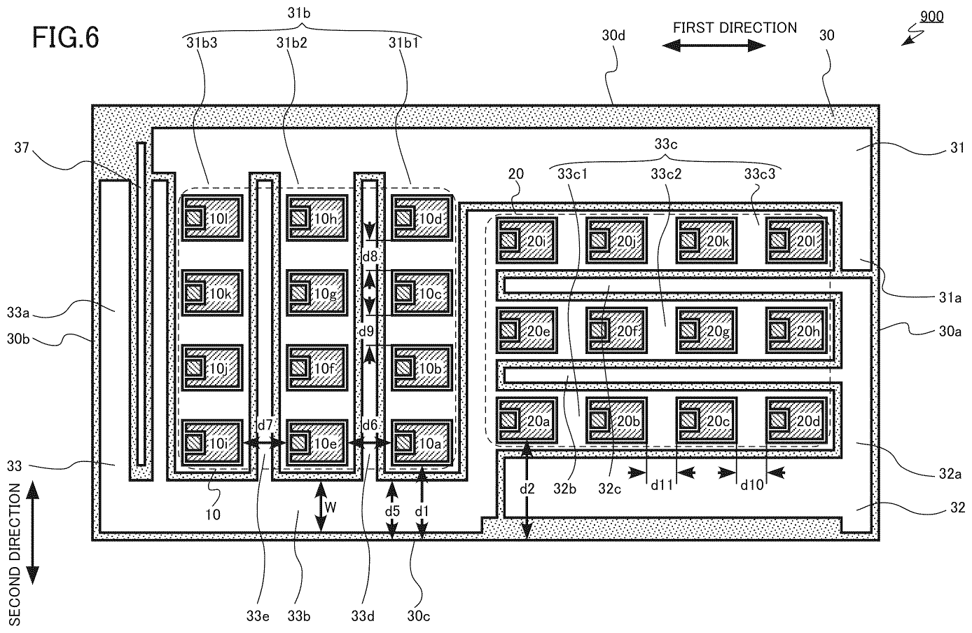

FIG. 6 is a schematic top view of a part of the semiconductor device according to the comparative example. FIG. 6 is a diagram corresponding to FIG. 4 in the first embodiment.

The semiconductor device according to the comparative example is a power semiconductor module 900. The power semiconductor module 900 is different from the power semiconductor module 100 according to the first embodiment in that the first distance (d1 in FIG. 6) between the first high-side MOSFET 10a and the third side 30c in the second direction is smaller than the second distance (d2 in FIG. 6) between the end of the first low-side MOSFET 20a on the side of the third side 30c and the third side 30c in the second direction.

The power semiconductor module 900 is different from the power semiconductor module 100 according to the first embodiment in that the center position of the high-side MOSFET group 10 in the second direction and the center position of the low-side MOSFET group 20 in the second direction are the same position in the second direction.

In the power semiconductor module 900, since the center position of the high-side MOSFET group 10 in the second direction and the center position of the low-side MOSFET group 20 in the second direction are the same position in the second direction, thermal interference between the high-side MOSFET group 10 and the low-side MOSFET group 20 is likely to occur. Therefore, the thermal resistance of the power semiconductor module 900 increases.

In addition, the power semiconductor module 900 is different from the power semiconductor module 100 according to the first embodiment in that the fifth distance (d5 in FIG. 6) between the end of the fifth region 33b of the third metal layer 33 on the side of the fourth side 30d and the third side 30c in the second direction is smaller than the second distance d2. The width (W in FIG. 6) of the fifth region 33b of the power semiconductor module 900 in the second direction is smaller than the width (W in FIG. 4) of the fifth region 33b of the power semiconductor module 100 in the second direction.

In the power semiconductor module 900, since the width (W in FIG. 6) of the fifth region 33b of the third metal layer 33 in the second direction becomes smaller, the electrical resistance between the positive terminal P and the AC output terminal AC and the electrical resistance between the negative terminal N and the AC output terminal AC become higher. Therefore, the power loss of the power semiconductor module 900 increases.

In addition, the power semiconductor module 900 is different from the power semiconductor module 100 according to the first embodiment in that the sixth distance (d6 in FIG. 6) between the first high-side MOSFET 10a and the fifth high-side MOSFET 10e in the first direction is equal to the seventh distance (d7 in FIG. 6) between the fifth high-side MOSFET 10e and the ninth high-side MOSFET 10i in the first direction.

In addition, the power semiconductor module 900 is different from the power semiconductor module 100 according to the first embodiment in that the eighth distance (d8 in FIG. 6) between the fourth high-side MOSFET 10d and the third high-side MOSFET 10c in the second direction is equal to the ninth distance (d9 in FIG. 6) between the third high-side MOSFET 10c and the second high-side MOSFET 10b in the second direction. In addition, the power semiconductor module 900 is different from the power semiconductor module 100 according to the first embodiment in that the ninth distance d9 is equal to the distance between the second high-side MOSFET 10b and the first high-side MOSFET 10a in the second direction.

In addition, the power semiconductor module 900 is different from the power semiconductor module 100 according to the first embodiment in that the tenth distance (d10 in FIG. 6) between the fourth low-side MOSFET 20d and the third low-side MOSFET 20c in the first direction is equal to the eleventh distance (d11 in FIG. 6) between the third low-side MOSFET 20c and the second low-side MOSFET 20b in the first direction. In addition, the power semiconductor module 900 is different from the power semiconductor module 100 according to the first embodiment in that the eleventh distance d11 is equal to the distance between the second low-side MOSFET 20b and the first low-side MOSFET 20a in the first direction.

In a power semiconductor module, a temperature rise is likely to occur due to thermal interference between two adjacent MOSFETs located near the central portion of the insulating substrate 30. In the power semiconductor module 900, the distance between two adjacent MOSFETs located near the central portion of the insulating substrate 30 is equal to the distance between two adjacent MOSFETs located far from the central portion of the insulating substrate 30. Therefore, thermal interference near the central portion of the insulating substrate 30 increases, and the thermal resistance of the power semiconductor module 900 increases.

In the power semiconductor module 900, since the thermal resistance is large and the power loss is large, it is difficult to reduce the size of the cooling system for cooling the power semiconductor module 900.

In the power semiconductor module 100 according to the first embodiment, the first distance (d1 in FIG. 4) between the first high-side MOSFET 10a and the third side 30c in the second direction is larger than the second distance (d2 in FIG. 4) between the first low-side MOSFET 20a and the third side 30c in the second direction. For this reason, the center position of the high-side MOSFET group 10 in the second direction and the center position of the low-side MOSFET group 20 in the second direction are shifted from each other in the second direction. In other words, the high-side MOSFET group 10 are shifted in the second direction from the low-side MOSFET group 20.

Therefore, thermal interference between the high-side MOSFET group 10 and the low-side MOSFET group 20 is less likely to occur. As a result, the thermal resistance of the power semiconductor module 100 is reduced.

In addition, in the power semiconductor module 100, the fifth distance (d5 in FIG. 4) between the end of the fifth region 33b of the third metal layer 33 on the side of the fourth side 30d and the third side 30c is larger than the second distance d2. The width (W in FIG. 4) of the fifth region 33b of the power semiconductor module 100 in the second direction is larger than the width (W in FIG. 6) of the fifth region 33b of the power semiconductor module 900 in the second direction.

In the power semiconductor module 100, since the width (W in FIG. 4) of the fifth region 33b of the third metal layer 33 in the second direction becomes larger, the electrical resistance between the positive terminal P and the AC output terminal AC and the electrical resistance between the negative terminal N and the AC output terminal AC become lower. Therefore, the power loss of the power semiconductor module 100 is reduced.

In addition, in the power semiconductor module 100 according to the first embodiment, the sixth distance (d6 in FIG. 4) between the first high-side MOSFET 10a and the fifth high-side MOSFET 10e in the first direction is larger than the seventh distance (d7 in FIG. 4) between the fifth high-side MOSFET 10e and the ninth high-side MOSFET 10i in the first direction.

In addition, in the power semiconductor module 100 according to the first embodiment, the eighth distance (d8 in FIG. 4) between the fourth high-side MOSFET 10d and the third high-side MOSFET 10c in the second direction is smaller than the ninth distance (d9 in FIG. 4) between the third high-side MOSFET 10c and the second high-side MOSFET 10b in the second direction. In addition, the ninth distance d9 is smaller than the distance between the second high-side MOSFET 10b and the first high-side MOSFET 10a in the second direction.

In addition, in the power semiconductor module 100 according to the first embodiment, the tenth distance (d10 in FIG. 4) between the fourth low-side MOSFET 20d and the third low-side MOSFET 20c in the first direction is smaller than the eleventh distance (d11 in FIG. 4) between the third low-side MOSFET 20c and the second low-side MOSFET 20b in the first direction. In addition, the eleventh distance d11 is smaller than the distance between the second low-side MOSFET 20b and the first low-side MOSFET 20a in the first direction.

By making the distance between two adjacent MOSFETs located near the central portion of the insulating substrate 30, where a temperature rise due to thermal interference between MOSFETs is likely to occur, larger than the distance between two adjacent MOSFETs located far from the central portion of the insulating substrate 30, the thermal resistance of the power semiconductor module 100 can be further reduced.

In the power semiconductor module 100, since the thermal resistance is reduced and the power loss is reduced, it is possible to reduce the size of the cooling system for cooling the power semiconductor module 100.

From the viewpoint of reducing the thermal resistance of the power semiconductor module 100, it is preferable that the first distance d1 is smaller than the third distance (d3 in FIG. 4) between the fifth low-side MOSFET 20e and the third side 30c in the second direction. If the first distance d1 becomes too large, the spacing between the MOSFETs forming the high-side MOSFET group 10 in the second direction becomes narrow. Therefore, since the thermal interference between the MOSFETs adjacent to each other in the second direction increases, there is a risk that the thermal resistance of the power semiconductor module 100 will increase.

From the viewpoint of reducing the power loss of the power semiconductor module 100, it is preferable that the width (W in FIG. 4) of the fifth region 33b in the second direction is larger than the second length (L2 in FIG. 4) of the first high-side MOSFET 10a in the second direction. In addition, from the viewpoint of reducing the power loss of the power semiconductor module 100, it is preferable that the width W of the fifth region 33b in the second direction is equal to or more than 5 mm.

As described above, according to the first embodiment, since the thermal resistance and power loss of the semiconductor module are reduced, the size of the cooling system for cooling the semiconductor module can be reduced.

### Second Embodiment

A semiconductor device according to a second embodiment is different from the semiconductor device according to the first embodiment in that the fifth distance between the end of the fifth region on a side of the fourth side and the third side in the second direction is smaller than the second distance. Hereinafter, the description of a part of the content overlapping the first embodiment may be omitted.

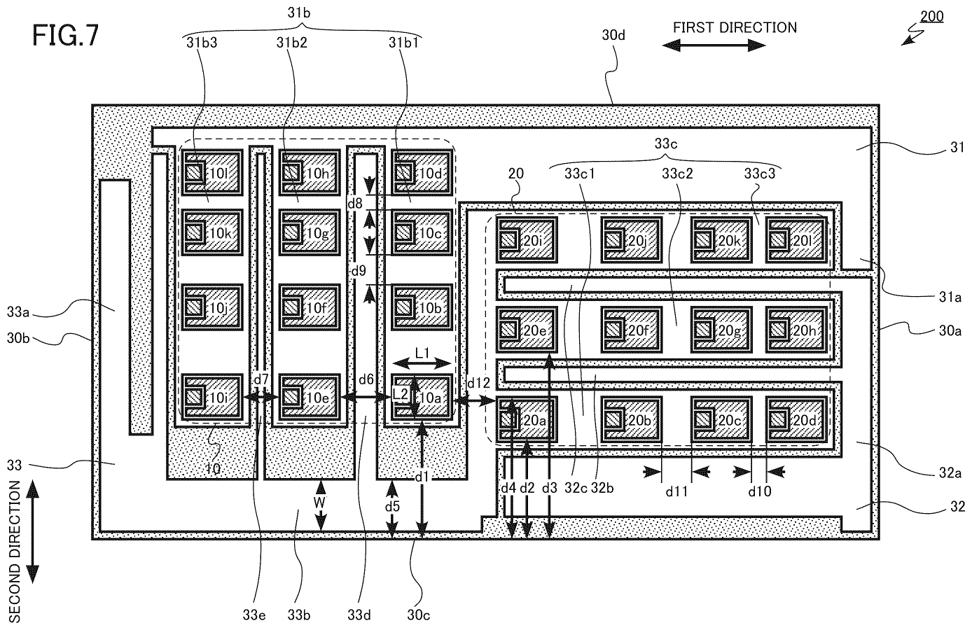

FIG. 7 is a schematic top view of a part of the semiconductor device according to the second embodiment. FIG. 7 is a diagram corresponding to FIG. 4 in the first embodiment.

The semiconductor device according to the second embodiment is a power semiconductor module 200. The power semiconductor module 200 is different from the power semiconductor module 100 according to the first embodiment in that the fifth distance (d5 in FIG. 7) between the end of the fifth region 33b of the third metal layer 33 on the side of the fourth side 30d and the third side 30c in the second direction is smaller than the second distance d2.

As described above, according to the second embodiment, since the thermal resistance of the semiconductor module is reduced, the size of the cooling system for cooling the semiconductor module can be reduced.

### Third Embodiment

A semiconductor device according to a third embodiment is different from the semiconductor device according to the first embodiment in that the second region does not include the first portion, the second portion, and the third portion, the third metal layer does not include the seventh region and the eighth region, the sixth region does not include the fourth portion, the fifth portion, and the sixth portion, and the second metal layer does not include the ninth region and the tenth region. Hereinafter, the description of a part of the content overlapping the first embodiment may be omitted.

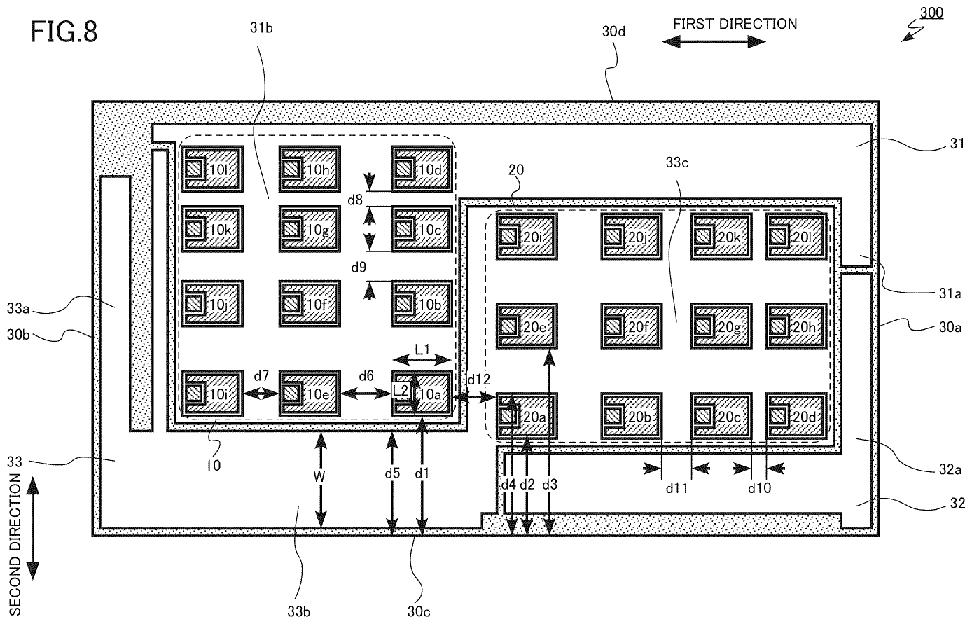

FIG. 8 is a schematic top view of a part of the semiconductor device according to the third embodiment. FIG. 8 is a diagram corresponding to FIG. 4 in the first embodiment.

The semiconductor device according to the third embodiment is a power semiconductor module 300. The second region 31b of the first metal layer 31 of the power semiconductor module 300 does not include the first portion 31b1, the second portion 31b2, and the third portion 31b3. In addition, the third metal layer 33 of the power semiconductor module 300 does not include the seventh region 33d and the eighth region 33e. In addition, the sixth region 33c of the third metal layer 33 of the power semiconductor module 300 does not include the fourth portion 33c1, the fifth portion 33c2, and the sixth portion 33c3. In addition, the second metal layer 32 of the power semiconductor module 300 does not include the ninth region 32b and the tenth region 32c.

As described above, according to the third embodiment, since the thermal resistance and power loss of the semiconductor module are reduced, the size of the cooling system for cooling the semiconductor module can be reduced.

### Fourth Embodiment

A semiconductor device according to a fourth embodiment is different from the semiconductor device according to the first embodiment in that the sixth distance between the first semiconductor chip and the fourth semiconductor chip in the first direction is equal to the seventh distance between the fourth semiconductor chip and the fifth semiconductor chip in the first direction, the eighth distance between the seventh semiconductor chip and the eighth semiconductor chip in the second direction is equal to the ninth distance between the eighth semiconductor chip and the ninth semiconductor chip in the second direction, and the tenth distance between the tenth semiconductor chip and the eleventh semiconductor chip in the first direction is equal to the eleventh distance between the eleventh semiconductor chip and the twelfth semiconductor chip in the first direction. Hereinafter, the description of a part of the content overlapping the first embodiment may be omitted.

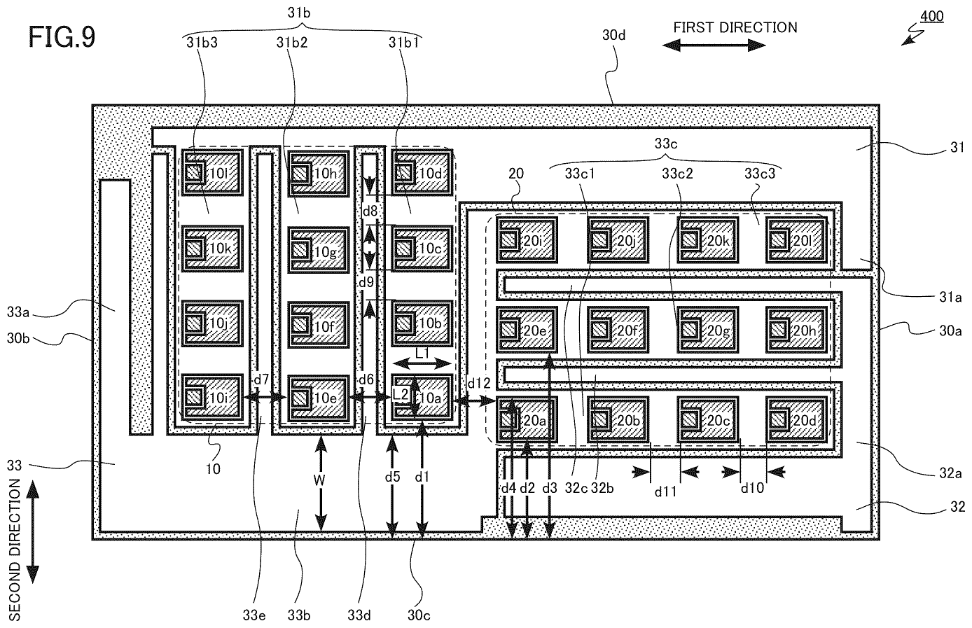

FIG. 9 is a schematic top view of a part of the semiconductor device according to the fourth embodiment. FIG. 9 is a diagram corresponding to FIG. 4 in the first embodiment.

The semiconductor device according to the fourth embodiment is a power semiconductor module 400. In the power semiconductor module 400, the sixth distance (d6 in FIG. 9) between the first high-side MOSFET 10a and the fifth high-side MOSFET 10e in the first direction is equal to the seventh distance (d7 in FIG. 9) between the fifth high-side MOSFET 10e and the ninth high-side MOSFET 10i in the first direction. In addition, in the power semiconductor module 400, the eighth distance (d8 in FIG. 9) between the fourth high-side MOSFET 10d and the third high-side MOSFET 10c in the second direction is equal to the ninth distance (d9 in FIG. 9) between the third high-side MOSFET 10c and the second high-side MOSFET 10b in the second direction. In addition, the tenth distance (d10 in FIG. 9) between the fourth low-side MOSFET 20d and the third low-side MOSFET 20c in the first direction is equal to the eleventh distance (d11 in FIG. 9) between the third low-side MOSFET 20c and the second low-side MOSFET 20b in the first direction.

As described above, according to the fourth embodiment, since the thermal resistance and power loss of the semiconductor module are reduced, the size of the cooling system for cooling the semiconductor module can be reduced.

In the first to fourth embodiments, the case where the MOSFET is used as a semiconductor chip has been described as an example. However, the semiconductor chip is not limited to the MOSFET. For example, other transistors such as IGBTs can be applied as semiconductor chips. In addition, as a power semiconductor chip, for example, a MOSFET without a built-in SBD can also be applied.

In the first to fourth embodiments, the case where the number of semiconductor chips arranged in parallel is 12 has been described as an example. However, the number of semiconductor chips may be four or more.

In the first to fourth embodiments, the case where the semiconductor chip is formed by using silicon carbide (SiC) has been described as an example. However, the semiconductor chip may be a semiconductor chip formed by using other semiconductors such as silicon or gallium nitride, for example.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
an insulating substrate having a first side, a second side opposite to the first side in a first direction, a third side, and a fourth side opposite to the third side in a second direction perpendicular to the first direction;
a first terminal provided on a side of the first side;
a second terminal provided on the side of the first side;
an output terminal provided on a side of the second side;
a first metal layer provided on the insulating substrate, including a first region and a second region, and electrically connected to the first terminal in the first region;
a second metal layer provided on the insulating substrate, including a third region, and electrically connected to the second terminal in the third region;
a third metal layer provided on the insulating substrate, including a fourth region, a fifth region, and a sixth region, and electrically connected to the output terminal in the fourth region, the sixth region being provided between the second region and the first side and the fifth region being provided between the second region and the third side;
a first semiconductor chip group provided on the second region and including a plurality of semiconductor chips arranged in a matrix in the first and second directions, each semiconductor chip having a first upper electrode and a first lower electrode, the first upper electrode being electrically connected to the third metal layer, and the first lower electrode being electrically connected to the first metal layer; and
a second semiconductor chip group provided on the sixth region and including a plurality of semiconductor chips arranged in a matrix in the first and second directions, each semiconductor chip having a second upper electrode and a second lower electrode, the second upper electrode being electrically connected to the second metal layer, and the second lower electrode being electrically connected to the third metal layer,
wherein the first semiconductor chip group includes a first semiconductor chip closest to the first side and the third side in the first semiconductor chip group,
the second semiconductor chip group includes a second semiconductor chip closest to the second side and the third side in the second semiconductor chip group and a third semiconductor chip adjacent to the second semiconductor chip in the second direction,
a first distance between the first semiconductor chip and the third side in the second direction is larger than a second distance between the second semiconductor chip and the third side in the second direction, and
the first distance is smaller than a third distance between the third semiconductor chip and the third side in the second direction.

2. The semiconductor device according to claim 1,
wherein the first distance is smaller than a fourth distance between an end of the second semiconductor chip on a side of the fourth side and the third side in the second direction.

3. The semiconductor device according to claim 1,
wherein a fifth distance between an end of the fifth region on a side of the fourth side and the third side in the second direction is larger than the second distance.

4. The semiconductor device according to claim 1,
wherein the first semiconductor chip group further includes a fourth semiconductor chip adjacent to the first semiconductor chip in the first direction and provided between the first semiconductor chip and the second side and a fifth semiconductor chip adjacent to the fourth semiconductor chip in the first direction and provided between the fourth semiconductor chip and the second side, and
a sixth distance between the first semiconductor chip and the fourth semiconductor chip in the first direction is larger than a seventh distance between the fourth semiconductor chip and the fifth semiconductor chip in the first direction.

5. The semiconductor device according to claim 4,
wherein the second region has a first portion extending in the second direction, a second portion extending in the second direction, and a third portion extending in the second direction,
the third metal layer further includes a seventh region connected to the fifth region and extending in the second direction and an eighth region connected to the fifth region and extending in the second direction,
the first semiconductor chip is provided on the first portion, the fourth semiconductor chip is provided on the second portion, and the fifth semiconductor chip is provided on the third portion, and
the seventh region is provided between the first portion and the second portion, and the eighth region is provided between the second portion and the third portion.

6. The semiconductor device according to claim 5,
wherein the second semiconductor chip group further includes a sixth semiconductor chip adjacent to the third semiconductor chip in the second direction and provided between the third semiconductor chip and the fourth side,
the sixth region has a fourth portion extending in the first direction, a fifth portion extending in the first direction, and a sixth portion extending in the first direction,
the second metal layer further includes a ninth region connected to the third region and extending in the first direction and a tenth region connected to the third region and extending in the first direction,
the second semiconductor chip is provided on the fourth portion, the third semiconductor chip is provided on the fifth portion, and the sixth semiconductor chip is provided on the sixth portion, and
the ninth region is provided between the fourth portion and the fifth portion, and the tenth region is provided between the fifth portion and the sixth portion.

7. The semiconductor device according to claim 1,
wherein the first semiconductor chip group further includes a seventh semiconductor chip closest to the first side and the fourth side in the first semiconductor chip group, an eighth semiconductor chip adjacent to the seventh semiconductor chip in the second direction and provided between the seventh semiconductor chip and the third side, and a ninth semiconductor chip adjacent to the eighth semiconductor chip in the second direction and provided between the eighth semiconductor chip and the third side, and
an eighth distance between the seventh semiconductor chip and the eighth semiconductor chip in the second direction is smaller than a ninth distance between the eighth semiconductor chip and the ninth semiconductor chip in the second direction.

8. The semiconductor device according to claim 1,
wherein the second semiconductor chip group further includes a tenth semiconductor chip closest to the first side and the third side in the second semiconductor chip group, an eleventh semiconductor chip adjacent to the tenth semiconductor chip in the first direction and provided between the tenth semiconductor chip and the second side, and a twelfth semiconductor chip adjacent to the eleventh semiconductor chip in the second direction and provided between the eleventh semiconductor chip and the second side, and
a tenth distance between the tenth semiconductor chip and the eleventh semiconductor chip in the first direction is smaller than an eleventh distance between the eleventh semiconductor chip and the twelfth semiconductor chip in the first direction.

9. The semiconductor device according to claim 1,
wherein a twelfth distance between the first semiconductor chip and the second semiconductor chip in the first direction is smaller than a first length of the first semiconductor chip in the first direction.

10. The semiconductor device according to claim 1,
wherein the first semiconductor chip group further includes a thirteenth semiconductor chip closest to the first side and the fourth side in the first semiconductor chip group,
the second semiconductor chip group further includes a fourteenth semiconductor chip closest to the second side and the fourth side in the second semiconductor chip group, and
a thirteenth distance between the thirteenth semiconductor chip and the fourth side in the second direction is smaller than a fourteenth distance between the fourteenth semiconductor chip and the fourth side in the second direction.

11. The semiconductor device according to claim 1,
wherein a width of the fifth region in the second direction is larger than a second length of the first semiconductor chip in the second direction.

12. The semiconductor device according to claim 1,
wherein a width of the fifth region in the second direction is equal to or more than 5 mm.

13. The semiconductor device according to claim 1,
wherein each semiconductor chip in the first semiconductor chip group and each semiconductor chip in the second semiconductor chip group further include a silicon carbide layer.

14. The semiconductor device according to claim 13,
wherein each semiconductor chip in the first semiconductor chip group and each semiconductor chip in the second semiconductor chip group are MOSFETs.

15. The semiconductor device according to claim 14,
wherein the MOSFET includes a Schottky barrier diode.
